(19) United States
(12) Patent Application Publication
(10) Pub. No.: US 2008/0123271 A1
(43) Pub. Date: May 29, 2008

(54) Flat panel display with sandwiched grounding member

(75) Inventor: Wei Shu, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignees: INNOCOM TECHNOLOGY CO., LTD; INNOLUX DISPLAY CORP.

(21) Appl. No.: 11/821,728

(22) Filed: Jun. 25, 2007

(30) Foreign Application Priority Data
Jun. 23, 2006 (TW) 95122735

(51) Int. Cl. H05K 5/02

(52) U.S. Cl. 361/681; 248/917

(57) ABSTRACT

An exemplary flat panel display (1) includes a top bezel (10), a display module (12), a bottom tray (14), and a grounding member (16). The top bezel includes a first protrusion (105). The bottom tray is engaged to the top bezel, and includes a second protrusion corresponding to the first protrusion. The display module is substantially accommodated by the bottom tray. A portion of the grounding member is held between the first protrusion and the second protrusion.

### FIELD OF THE INVENTION

The present invention relates to a flat panel display (FPD) that includes a clipped grounding member.

### GENERAL BACKGROUND

Flat panel displays are commonly used as display devices in a variety of products including compact electronic apparatuses. Referring to FIG. 6, one kind of typical flat panel display 6 includes a top bezel 60, a display module 61, a bottom tray 62, a screw 63, a grounding wire 64, and a conductive gasket 65. The top bezel 60, the display module 61, and the bottom tray 62 are arranged substantially in that order from top to bottom. The top bezel 60 is four-sided, and thus defines a window (not labeled) for allowing viewing of the display module 61. One end (not labeled) of the grounding wire 64 is connected to the gasket 65.

Referring also to FIG. 7, when the flat panel display 6 is assembled, the display module 61 is received in the bottom tray 62, and is secured by the top bezel 60 and the bottom tray 62. The screw 63 is extended through the gasket 65, and is threadedly engaged in a through hole (not labeled) defined in a side portion of the bottom tray 62. The bottom tray 62 thus is grounded via the grounding wire 64 and the gasket 65.

However, the step of engaging the screw 63 to the bottom tray 62 is typically performed by manual labor. In addition, the grounding wire 64 needs to be connected to the gasket 65 beforehand. These factors limit the efficiency of manufacturing of the flat panel display 6, and contribute to the cost of manufacturing the flat panel display 6.

What is needed, therefore, is a flat panel display that can overcome the above-described limitations or deficiencies.

### SUMMARY

In one preferred embodiment, a flat panel display includes a top bezel, a bottom tray, a display module, and a grounding member. The top bezel includes a first protrusion. The bottom tray is engaged to the top bezel, and includes a second protrusion corresponding to the first protrusion. The display module is substantially accommodated by the bottom tray. A portion of the grounding member is held between the first protrusion and the second protrusion.

Other novel features, advantages and aspects will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of at least one embodiment of the present invention. In the drawings, like reference numerals designate corresponding parts throughout various views, and all the views are schematic.

FIG. 1 is an exploded, isometric view of a flat panel display according to a first embodiment of the present invention.

FIG. 2 is an assembled view of the flat panel display of FIG. 1.

FIG. 3 is a cross-sectional view take along line III-III of FIG. 2, showing part of the flat panel display.

FIG. 4 is similar to FIG. 3, but showing a corresponding view in the case of a flat panel display according to a second embodiment of the present invention.

FIG. 5 is similar to FIG. 3, but showing a corresponding view in the case of a flat panel display according to a third embodiment of the present invention.

FIG. 6 is an exploded, isometric view of a conventional flat panel display.

FIG. 7 is an assembled view of the flat panel display of FIG. 6.

### DETAILED DESCRIPTION OF PREFERRED EMBODIMENTS

Reference will now be made to the drawings to describe preferred embodiments of the present invention in detail.

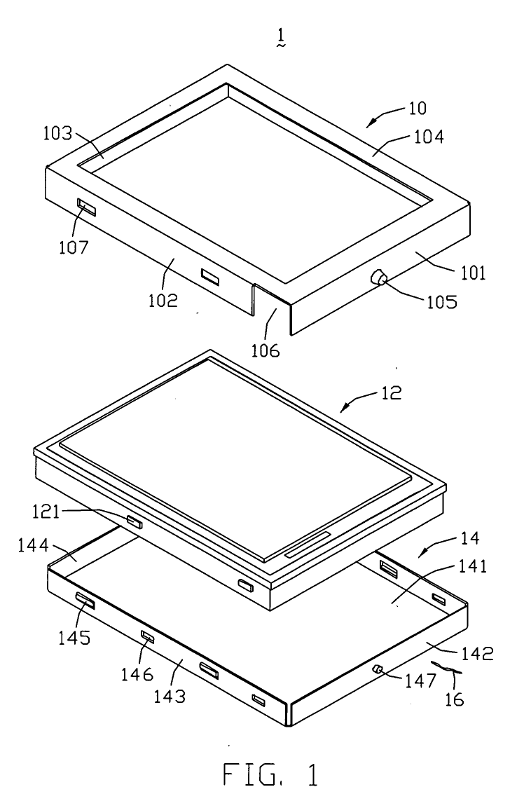

Referring to FIG. 1, a flat panel display 1 according to a first embodiment of the present invention is shown. The flat panel display 1 includes a top bezel 10, a display module 12, a bottom tray 14, and a grounding wire 16. The top bezel 10, the display module 12, and the bottom tray 14 are arranged substantially in that order from top to bottom.

The top bezel 10 includes a first bezel portion 101, a second bezel portion 102, a third bezel portion 103, and a fourth bezel portion 104, which are located in that sequence to form a closed structure that is the top bezel 10. The first, second, third, and fourth bezel portions 101, 102, 103, 104 cooperatively define a window (not labeled) therebetween, for allowing viewing of the display module 12. The first bezel portion 101 is opposite to the third bezel portion 103, and includes a first hollow protrusion 105 outwardly extending therefrom. In the illustrated embodiment, the first protrusion 105 extends from a central part of the first bezel portion 101. The second bezel portion 102 is opposite to the fourth bezel portion 104, and has a rectangular opening 106 defined adjacent the first bezel portion 101. Each of the second bezel portion 102 and the fourth bezel portion 104 includes a pair of first notches 107 defined therein. In general, the top bezel 10 is made from iron, aluminum, magnesium, any suitable alloy of these, or another suitable material.

The display module 12 is essentially rectangular. Each of two opposite horizontal sides (not labeled) of the display module 12 includes a pair of first ears 121 outwardly extending therefrom. In the illustrated embodiment, the display module 12 is a liquid crystal module.

The bottom tray 14 includes a bottom plate 141, a first side plate 142, two opposite second side plates 143, and a third side plate 144 opposite to the first side plate 142. The first side plate 142, the second side plates 143, and the third side plate 144 perpendicularly extend from respective edges of the bottom plate 141, thus cooperatively defining a housing (not labeled) for receiving the display module 12. Each of the second side plates 143 includes a pair of second ears 145 outwardly extending therefrom, and a pair of second notches 146 defined therein. The second ears 145 respectively correspond to the first notches 107 of the top bezel 10, and the second notches 146 respectively correspond to the first ears 121 of the display module 12. In general, the bottom tray 14 is made from iron, aluminum, magnesium, any suitable material that includes an alloy of these, or another suitable material.

The first side plate 142 includes a second hollow protrusion 147 outwardly extending therefrom. The second protrusion 147 corresponds to the first protrusion 105, and a size of the second protrusion 147 is slightly less than that of the first protrusion 105. In an alternative embodiment, the second protrusion 147 can have a solid configuration. The first protrusion 105 and the second protrusion 147 can be manufactured by a pressing or stamping method.

The grounding wire 16 is a conductive wire. For example, the grounding wire 16 can be made from iron, copper, a material that includes an alloy of these, or another suitable alloy.

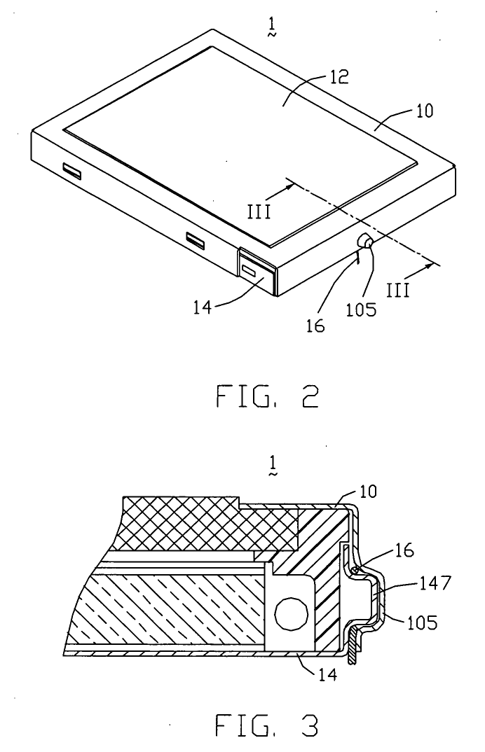

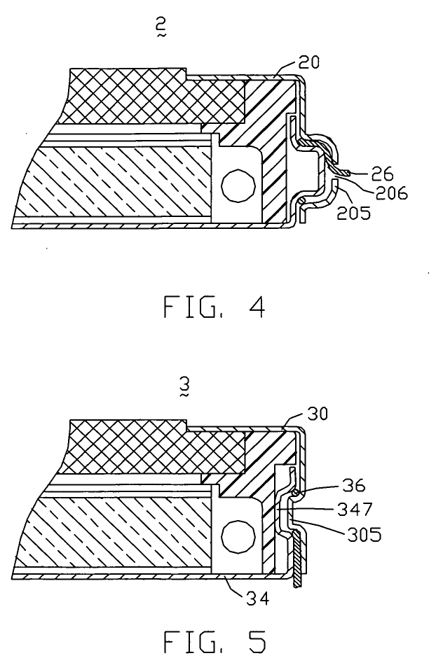

Referring also to FIG. 2 and FIG. 3, when the flat panel display 1 is assembled, the display module 12 is accommodated by the bottom tray 14. The second protrusion 147 is fittingly received in the first protrusion 105. One end (not labeled) of the grounding wire 16 is firmly held between the first protrusion 105 and the second protrusion 147, and the other terminal (not labeled) is exposed out of a bottom of the top bezel 10. Typically, said one end of the grounding wire 16 is interferentially sandwiched between the first and second protrusions 105, 147. The first ears 121 of the display module 12 are respectively fixed in the second notches 146 of the bottom tray 14, and the second ears 145 of the bottom tray 14 are respectively fixed in the first notches 107 of the top bezel 10.

Because the grounding wire 16 is held between the first protrusion 105 and the second protrusion 147, the flat panel display 1 can be grounded without the need for providing a screw and without the need for engaging such screw. Furthermore, if the grounding wire 16 needs to be removed from the flat panel display 1, there is no need for disengaging any screw. In summary, the grounding wire 16 can be secured to or removed from the flat panel display 1 conveniently, and a cost of manufacturing the flat panel display 1 is reduced.

Referring to FIG. 4, a flat panel display 2 according to a second embodiment of the present invention is similar to the flat panel display 1. However, the flat panel display 2 includes a top bezel 20 having a first bezel portion (not labeled). The first bezel portion includes a hollow protrusion 205 outwardly extending therefrom. The protrusion 205 includes a through hole 206 defined therein, for providing an exit for a grounding wire 26 of the flat panel display 2. In other respects, the flat panel display 2 has features and advantages similar to those described above in relation to the flat panel display 1.

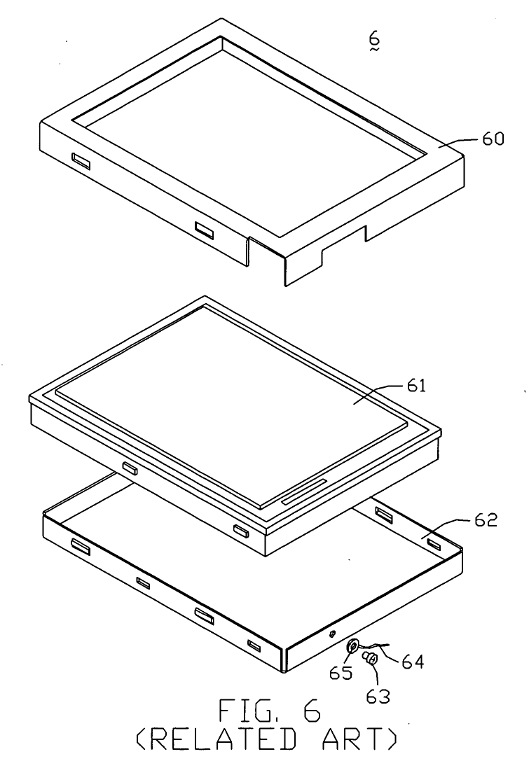

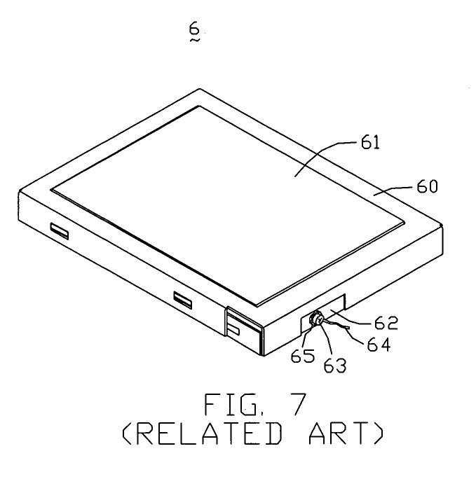

Referring to FIG. 5, a flat panel display 3 according to a third embodiment of the present invention is similar to the flat panel display 1. However, the flat panel display 3 includes a top bezel 30, a display module (not labeled), a bottom tray 34, and a grounding wire 36. The top bezel 30 includes a first bezel portion (not labeled). The first bezel portion includes a first protrusion 305 inwardly extending therefrom. The bottom tray 34 includes a first side portion (not labeled). The first side portion includes a second hollow protrusion 347 inwardly extending therefrom. The second protrusion 347 corresponds to the first protrusion 305, and has a size slightly greater than that of the first protrusion 305. The grounding wire 36 is firmly held between the first protrusion 305 and the second protrusion 347. Typically, the grounding wire 36 is interferentially sandwiched between the first and second protrusions 305, 347. The flat panel display 3 has advantages similar to those described above in relation to the flat panel display 1.

It is believed that the present embodiments and their advantages will be understood from the foregoing description, and it will be apparent that various changes may be made thereto without departing from the spirit or scope of the invention or sacrificing all of its material advantages, the examples hereinbefore described merely being preferred or exemplary embodiments of the invention.

What is claimed is:

1. A flat panel display comprising:
a top bezel comprising a first protrusion;
a bottom tray engaged to the top bezel, the bottom tray comprising a second protrusion corresponding to the first protrusion;
a display module substantially accommodated by the bottom tray; and
a grounding member, a portion of the grounding member held between the first protrusion and the second protrusion.

2. The flat panel display as claimed in claim 1, wherein the first protrusion outwardly extends from the top bezel.

3. The flat panel display as claimed in claim 2, wherein the second protrusion outwardly extends from the bottom tray.

4. The flat panel display as claimed in claim 3, wherein a size of the second protrusion is less than that of the first protrusion.

5. The flat panel display as claimed in claim 3, wherein the first protrusion has a hollow configuration.

6. The flat panel display as claimed in claim 5, wherein the second protrusion is at least partly accommodated in the first protrusion.

7. The flat panel display as claimed in claim 6, wherein the first protrusion comprises a through hole defined therein, and another portion of the grounding member extends out from the first protrusion through the through hole.

8. The flat panel display as claimed in claim 1, wherein the first protrusion inwardly extends from the top bezel.

9. The flat panel display as claimed in claim 8, wherein the second protrusion inwardly extends from the bottom tray.

10. The flat panel display as claimed in claim 9, wherein a size of the first protrusion is less than that of the second protrusion.

11. The flat panel display as claimed in claim 10, wherein the first protrusion has a hollow configuration.

12. The flat panel display as claimed in claim 10, wherein the first protrusion is at least partly accommodated in the second protrusion.

13. The flat panel display as claimed in claim 1, wherein the top bezel is made from iron, aluminum, magnesium, or a material comprising any alloy of these.

14. The flat panel display as claimed in claim 1, wherein the bottom tray is made from iron, aluminum, magnesium, or a material comprising any alloy of these.

15. The flat panel display as claimed in claim 1, wherein the top bezel comprises a plurality of first notches defined therein.

16. The flat panel display as claimed in claim 15, wherein the bottom tray comprises a plurality of first protrusions respectively engaged in the first notches of the top bezel.

17. The flat panel display as claimed in claim 16, wherein the bottom tray further comprises a plurality of second notches defined therein.

18. The flat panel display as claimed in claim 17, wherein the display module comprises a plurality of second protrusions respectively engaged in the second notches of the bottom tray.

19. A flat panel display comprising:
a top bezel;
a bottom tray engaged with the top bezel;
a display module at least partly accommodated by the bottom tray; and
a grounding member;
wherein the top bezel and the bottom tray have corresponding contoured portions that define a gap therebetween, and a portion of the grounding member is interferentially held between the top bezel and the bottom tray in the gap.

20. A flat panel display comprising:
a top bezel;
a bottom tray engaged with the top bezel and cooperating with the top bezel to form a contour with a receiving cavity therein;
a display module accommodated in the receiving cavity; and
a wire like grounding member; wherein
one of said the top bezel and the bottom tray forms a corresponding protruding portion extending toward the other, and said grounding member has a portion surrounding said protruding portion and another portion extending out of said contour to be exposed to an exterior.
